(19) United States
(12) Patent Application Publication
(10) Pub. No.: US 2024/0396585 A1
(43) Pub. Date: Nov. 28, 2024

(54) METHOD FOR CONTROLLING VOLTAGE SUPPLIED TO RF TRANSMISSION/RECEPTION MODULE, AND ELECTRONIC DEVICE FOR CARRYING OUT SAME

(71) Applicant: Samsung Electronics Co., Ltd., Suwon-si (KR)

(72) Inventors: Kyujae JANG, Suwon-si (KR); Hyeyong GO, Suwon-si (KR); Jungjoon KIM, Suwon-si (KR); Jihun KIM, Suwon-si (KR); Hyoungtak SON, Suwon-si (KR); Yeonsang YUN, Suwon-si (KR); Sangdon LEE, Suwon-si (KR); Jihyeon JANG, Suwon-si (KR); Sungyoul CHO, Suwon-si (KR)

(21) Appl. No.: 18/794,634

(22) Filed: Aug. 5, 2024

Related U.S. Application Data
(63) Continuation of application No. PCT/KR2023/004907, filed on Apr. 12, 2023.

(30) Foreign Application Priority Data
May 27, 2022 (KR) 10-2022-0065667
Jun. 29, 2022 (KR) 10-2022-0079930

(51) Int. Cl. H04B 1/40; G01R 19/165; H02M 3/158; H03F 1/30

(52) U.S. Cl. CPC H04B 1/40; G01R 19/16538; H02M 3/1582; H03F 1/30

(57) ABSTRACT

Disclosed are a method for controlling a voltage supplied to a radio frequency (RF) transmission/reception module, and an electronic device for carrying out same. The electronic device, according to an embodiment, comprises: a communication processor including at least one processor comprising processing circuitry; an RF integrated circuit configured to generate a RF signal by processing data received from the communication processor, and transmit the RF signal to a RF transmission/reception module; the RF transmission/reception module comprising an amplification circuit configured to amplify the RF signal, and an overvoltage protection circuit configured to reduce overvoltage-induced damage to the amplification circuit, and configured to transmit the amplified RF signal; and a power management integrated circuit configured to manage power supplied to the amplification circuit using a voltage converter comprising a boost circuit configured to step up a voltage input into the boost circuit and a buck circuit configured to step down a voltage input into the buck circuit, wherein at least one processor of the communication processor, individually and/or collectively, is configured to: use the overvoltage protection circuit to detect the occurrence of an overshoot in which a voltage supplied to the RF transmission/reception module exceeds a threshold value, and in response to detecting the occurrence of the overshoot, control the power management integrated circuit and thus reduce an operation time of the boost circuit.

### CROSS-REFERENCE TO RELATED APPLICATIONS

This application is a continuation of International Application No. PCT/KR2023/004907 designating the United States, filed on Apr. 12, 2023, in the Korean Intellectual Property Receiving Office and claiming priority to Korean Patent Application Nos. 10-2022-0065667, filed on May 27, 2022, and 10-2022-0079930, filed on Jun. 29, 2022, in the Korean Intellectual Property Office, the disclosures of each of which are incorporated by reference herein in their entireties.

### BACKGROUND

### Field

The disclosure relates to technology for controlling voltage supplied to a radio frequency (RF) transmission/reception module.

### Description of Related Art

An electronic device that transmits and receives a radio frequency (RF) signal may use an amplification circuit to amplify the RF signal. The electronic device may include a power management integrated circuit (PMIC) that supplies power to an amplification circuit. Since an amplification circuit consumes a lot of power to amplify an RF signal, the electronic device may include a PMIC, such as an envelope tracking (ET) modulator, to maintain high signal amplification efficiency of the amplification circuit. The PMIC may supply power needed for an amplification circuit using a switching regulator.

### SUMMARY

An electronic device according to an example embodiment includes: a communication processor comprising at least one processor comprising processing circuitry, a radio frequency (RF) integrated circuit configured to generate an RF signal by processing data received from the communication processor and configured to: transmit the RF signal to an RF transmission/reception module comprising circuitry, the RF transmission/reception module including an amplification circuit configured to amplify the RF signal and an overvoltage protection (OVP) circuit configured to reduce damage to the amplification circuit due to overvoltage, and configured to transmit the amplified RF signal, and a power management integrated circuit (PMIC) configured to manage power supplied to the amplification circuit using a voltage converter including a boost circuit configured to step up voltage input to the boost circuit and a buck circuit for stepping down voltage input to the buck circuit. At least one processor, individually and/or collectively, of the communication processor is configured to: detect occurrence of overshoot in which voltage supplied to the RF transmission/reception module exceeds a threshold value, using the OVP circuit; and reduce an operation time of the boost circuit by controlling the PMIC in response to the detection of the occurrence of the overshoot.

An electronic device according to an example embodiment includes: a communication processor comprising at least one processor comprising processing circuitry, an RF integrated circuit configured to generate an RF signal by processing data received from the communication processor and configured to transmit the RF signal to an RF transmission/reception module, the RF transmission/reception module including: an amplification circuit configured to amplify the RF signal and an overvoltage protection (OVP) circuit configured to reduce damage to the amplification circuit due to overvoltage, and configured to transmit the amplified RF signal, and a power management integrated circuit (PMIC) configured to manage power supplied to the amplification circuit using a voltage converter including a boost circuit configured to step up voltage input to the boost circuit and a buck circuit configured to step down voltage input to the buck circuit. At least one processor of the communication processor, individually and/or collectively, is configured to: detect occurrence of overshoot in which voltage supplied to the RF transmission/reception module exceeds a threshold value, using the OVP circuit; determine whether a difference value between output voltage of the PMIC and target output voltage is greater than a set value in response to the detection of the occurrence of the overshoot; and change bias current of the amplification circuit to a maximum bias current based on the difference value being greater than the set value.

An electronic device according to an example embodiment includes: a communication processor comprising at least one processor comprising processing circuitry, an RF integrated circuit configured to generate an RF signal by processing data received from the communication processor and configured to transmit the RF signal to an RF transmission/reception module, the RF transmission/reception module including: an amplification circuit configured to amplify the RF signal, and configured to transmit the amplified RF signal, and a power management integrated circuit (PMIC) configured to manage power supplied to the amplification circuit using a voltage converter including a boost circuit configured to step up voltage input to the boost circuit and a buck circuit configured to step down voltage input to the buck circuit. At least one processor of the communication processor, individually and/or collectively, is configured to: determine whether a difference value between output voltage of the PMIC and target output voltage is greater than a threshold difference value, increase the output voltage of the PMIC to an intermediate output voltage less than the target output voltage by controlling the PMIC based on the difference value being greater than the threshold difference value; and increase the output voltage of the PMIC to the target output voltage based on the output voltage of the PMIC reaching the intermediate output voltage.

A method of controlling voltage supplied to an RF transmission/reception module configured to transmit and receive an RF signal to and from an electronic device, according to an example embodiment, includes: detecting occurrence of overshoot in which the voltage supplied to the RF transmission/reception module exceeds a threshold value, using an overvoltage protection (OVP) circuit configured to reduce an amplification circuit, included in the RF transmission/reception module and configured to amplify an RF signal to be transmitted, from being damaged due to overvoltage, and using a voltage converter including a boost circuit and a buck circuit to reduce an operation time of the boost circuit by controlling a PMIC configured to supply power to the RF transmission/reception module in response to the detection of the occurrence of the overshoot.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example configuration of an electronic device according to various embodiments;

FIG. 2 is a graph illustrating overshoot that may occur in an electronic device, according to various embodiments;

FIG. 3 is a circuit diagram illustrating an example voltage converter included in a power management integrated circuit (PMIC), according to various embodiments;

FIGS. 4A and 4B are graphs illustrating an output of a voltage converter when overshoot occurs and when overshoot does not occur in an electronic device, according to various embodiments;

FIG. 5 is a flowchart illustrating an example method of controlling voltage supplied to a radio frequency (RF) transmission/reception module, according to various embodiments;

FIG. 6 is a flowchart illustrating an example method of controlling voltage supplied to an RF transmission/reception module, according to various embodiments;

FIG. 7 is a diagram illustrating an example of a circuit for controlling bias of an amplification circuit, according to various embodiments;

FIG. 8 is a graph illustrating output voltage of a PMIC controlled by an electronic device, according to various embodiments;

FIG. 9 is a flowchart illustrating an example method of controlling voltage supplied to an RF transmission/reception module, according to various embodiments;

FIG. 10 is a graph illustrating the maximum voltage value of overshoot to be reduced, by adjusting an output of a boost circuit, according to various embodiments;

FIG. 11 is a graph illustrating output voltage of a PMIC in a standby mode, according to various embodiments; and

FIG. 12 is a block diagram illustrating an example electronic device according to various embodiments.

### DETAILED DESCRIPTION

Hereinafter, various example embodiments will be described in greater detail with reference to the accompanying drawings. When describing the various example embodiments with reference to the accompanying drawings, like reference numerals refer to like elements and a repeated description related thereto may not be provided.

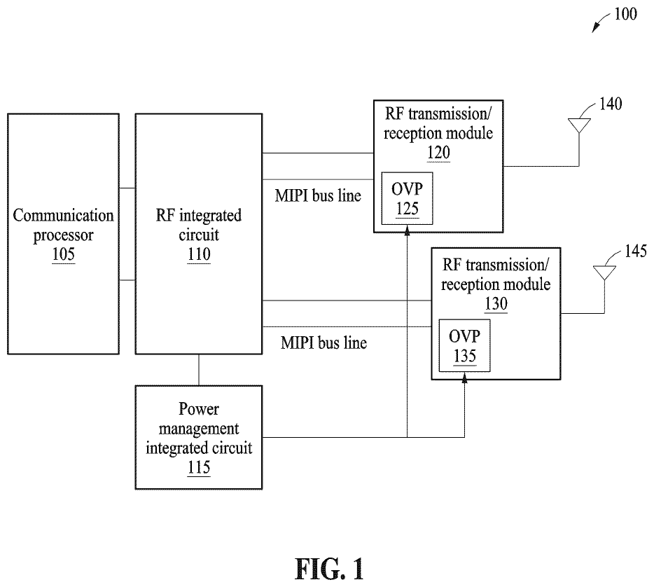

FIG. 1 is a block diagram illustrating an example configuration of an electronic device according to various embodiments.

Referring to FIG. 1, an electronic device 100 according to an embodiment may include a communication processor (e.g., including processing circuitry) 105 and a radio frequency (RF) integrated circuit (e.g., including various circuitry) 110 configured to generate an RF signal by processing data received from the communication processor 105 and configured to transmit the RF signal to at least one RF transmission/reception module (e.g., a first RF transmission/reception module (e.g., including various circuitry) 120 and a second RF transmission/reception module (e.g., including various circuitry) 130). The RF integrated circuit 110 may generate the RF signal by modulating the data received from the communication processor 105 or transmit an RF signal received from the outside to the communication processor 105 by demodulating the RF signal.

The electronic device 100 may include the at least one RF transmission/reception module (e.g., the first RF transmission/reception module 120 and the second RF transmission/reception module 130) including various RF circuitry. The RF transmission/reception module may include an amplification circuit for amplifying the RF signal, an overvoltage protection (OVP) circuit (e.g., a first OVP circuit 125 and a second OVP circuit 135) for reducing damage to the amplification circuit due to overvoltage, and an amplification circuit (not shown) for amplifying the RF signal, and may transmit the RF signal amplified in the amplification circuit through an antenna (e.g., a first antenna 140 and a second antenna 145).

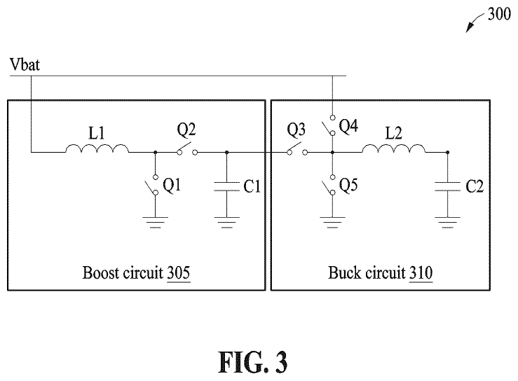

The electronic device 100 may include a power management integrated circuit (PMIC) 115 including various circuitry that supplies power to the at least one RF transmission/reception module (e.g., the first RF transmission/reception module 120 and the second RF transmission/reception module 130). The PMIC 115 may include a switching regulator (not shown) and may control current and voltage supplied to the at least one RF transmission/reception module (e.g., the first RF transmission/reception module 120 and the second RF transmission/reception module 130) using the switching regulator. For example, the PMIC 115 may manage power supplied to the amplification circuit using a voltage converter (not shown) (e.g., a voltage converter 300 of FIG. 3) including a boost circuit for stepping up voltage input to the boost circuit and a buck circuit for stepping down voltage input to the buck circuit. In an embodiment, the PMIC 115 may be controlled by the communication processor 105.

The PMIC 115 may control output voltage by controlling current flowing through an inductor included in the switching regulator with a switching operation, and in some cases, overshoot in which output voltage of the PMIC 115 exceeds target voltage may occur.

In an embodiment, the communication processor 105 may include at least one processor including various processing circuitry and determine whether overshoot in which voltage exceeding a threshold value is supplied to the RF transmission/reception module (e.g., the first transmission/reception module 120 and the second transmission/reception module 130) occurs using the OVP circuit (e.g., the first OVP circuit 125 and the second OVP circuit 135). In an embodiment, the threshold value may be the absolute maximum ratings (AMR) voltage of the amplification circuit. The communication processor 105 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

The OVP circuit (e.g., the first OVP circuit 125 and the second OVP circuit 135) may transmit an overvoltage generation signal to the RF integrated circuit 110 through a mobile industry processor interface (MIPI) bus line when the voltage supplied to the RF transmission/reception module (e.g., the first RF transmission/reception module 120 and the second RF transmission/reception module 130) exceeds the threshold value. The RF integrated circuit 110 may transmit the overvoltage generation signal to the communication processor 105, and the communication processor 105 may detect the occurrence of overshoot when the overvoltage generation signal is received.

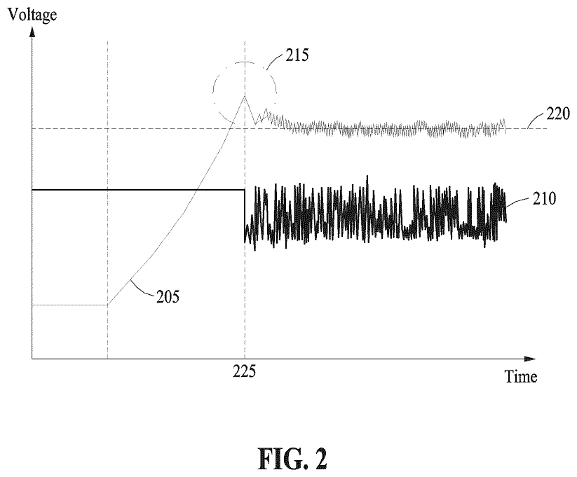

For example, FIG. 2 is a graph illustrating an example in which overshoot 215 occurs and overvoltage is supplied to an amplification circuit according to various embodiments. When the electronic device 100 desires to amplify an RF signal to transmit the RF signal, the electronic device 100 may control the PMIC 115 such that the PMIC 115 outputs power for amplifying the RF signal to the amplification circuit. The PMIC 115 may increase output voltage 205 of the PMIC 115 to target voltage 220 to supply power to the amplification circuit. The output voltage 205 of the PMIC 115 may be supplied to the amplification circuit. The overshoot 215 exceeding the target voltage 220 may occur while the PMIC 115 increases the output voltage 205. It may be assumed that voltage when the overshoot 215 occurs is voltage exceeding the AMR of the amplification circuit.

In the example of FIG. 2, an RF signal to be amplified may be input to the amplification circuit at a time point 225, and the amplification circuit may output an amplified RF signal 210 by amplifying the input RF signal. The amplification circuit may be damaged due to overvoltage when the overshoot 215 occurs at the time point 225 when the RF signal to be amplified is input to the amplification circuit and the amplification circuit operates.

The possibility of damage to the amplification circuit may increase when the overshoot 215 occurs and voltage exceeding the rating voltage range of the amplification circuit is frequently supplied to the amplification circuit. The electronic device 100 according to an embodiment may reduce the occurrence frequency of the overshoot 215 by controlling the output voltage 205 of the PMIC 115 and may reduce damage to the amplification circuit due to overvoltage.

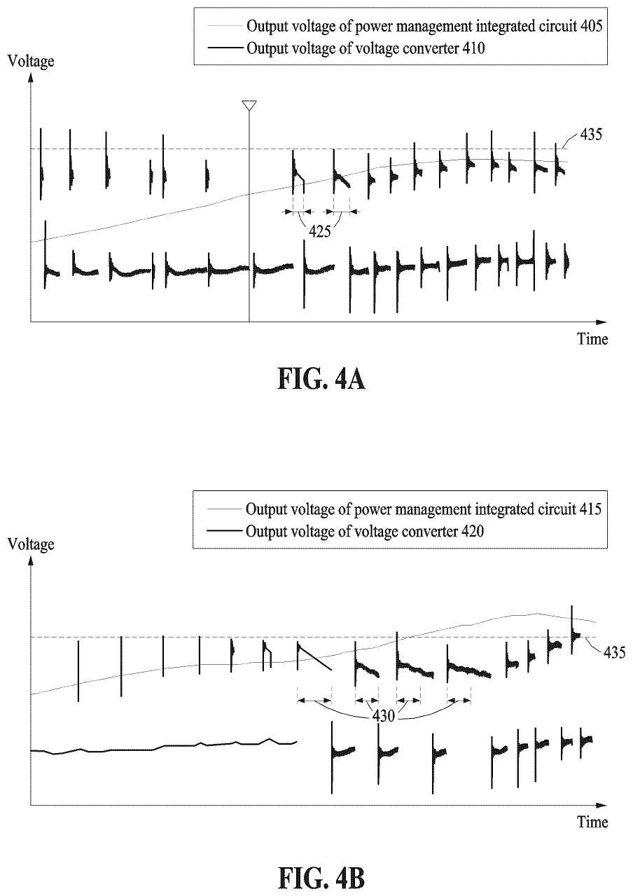

Hereinafter, a relationship between an output of a voltage converter and overshoot is described in greater detail with reference to FIGS. 3 and 4.

FIG. 3 is a circuit diagram illustrating an example configuration of the voltage converter 300 included in the PMIC 115 according to various embodiments.

In an embodiment, the PMIC 115 of the electronic device 100 may manage power supplied to an amplification circuit using the voltage converter 300 including a boost circuit 305 for stepping up input voltage and a buck circuit 310 for stepping down input voltage. The buck circuit 310 may be connected to the boost circuit 305 in a cascade structure.

The boost circuit 305 may include a first inductor L1 of which one end is connected to input voltage Vbat, a first switch Q1 configured to control a connection between the other end of the first inductor L1 and ground, a first capacitor C1 connected between the other end of the first inductor L1 and the ground, and a second switch Q2 configured to control a connection between the other end of the first inductor L1 and the first capacitor C1, and the buck circuit 310 may include a second inductor L2, a third switch Q3 configured to control a connection between the boost circuit 305 and one end of the second inductor L2 of the buck circuit, a fourth switch Q4 configured to control a connection between the input voltage Vbat and one end of the second inductor L2, a fifth switch Q5 configured to control a connection between one end of the second inductor L2 and the ground, and a second capacitor C2 connected between the other end of the second inductor L2 and the ground.

The voltage converter 300 may perform a boost operation for stepping up input voltage (e.g., the input voltage Vbat) by controlling switches of the boost circuit 305 and switches (e.g., the first switch Q1, the second switch Q2, the third switch Q3, the fourth switch Q4, and the fifth switch Q5) of the buck circuit 310 or a buck operation for outputting input voltage (e.g., the input voltage Vbat or output voltage of the boost circuit 305) by stepping down the input voltage or outputting the same voltage as the input voltage. For example, the voltage converter 300 may perform the boost operation by turning on the second switch Q2 and the third switch Q3 and turning off the first switch Q1, the fourth switch, and the fifth switch Q5 and may perform the buck operation by turning on the fourth switch Q4 and turning off the third switch Q3 and the fifth switch Q5. When performing the buck operation, the first switch Q1 and the second switch Q2 may be turned on or turned off.

Output voltage of the PMIC 115 may be controlled based on an output of the voltage converter 300.

FIGS. 4A and 4B are graphs illustrating output voltage 410 of a voltage converter measured when overshoot occurs in the PMIC 115 of the electronic device 100 and output voltage 420 of the voltage converter measured when overshoot does not occur according to various embodiments.

In the example of FIG. 4A, output voltage 405 of the PMIC 115 does not exceed target voltage 435, so overshoot may not occur, and in the example of FIG. 4B, output voltage 415 of the PMIC 115 exceeds target voltage 425, so overshoot may occur.

Comparing the time length of a section 435 in which the boost operation is performed in FIG. 4A with the time length of a section 430 in which the boost operation is performed in FIG. 4B, in the case of FIG. 4B in which overshoot occurs in the output voltage of the PMIC 115, the section 430 in which the boost operation is performed may be relatively longer.

The electronic device 100 according to an embodiment may detect whether overshoot of the output voltage of the PMIC 115 occurs through an OVP circuit and may reduce the overshoot of the output voltage of the PMIC 115 by reducing an operation time of the boost circuit of the voltage converter when the overshoot occurs.

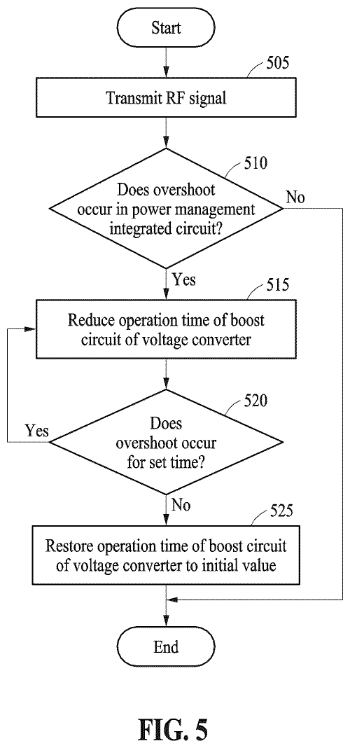

Hereinafter, according to an embodiment, a method of reducing an operation time of a boost circuit of a voltage converter by the electronic device 100 is described in greater detail with reference to FIG. 5.

FIG. 5 is a flowchart illustrating an example method of controlling voltage supplied to an RF transmission/reception module, according to various embodiments.

In operation 505, the electronic device 100 according to an embodiment may amplify an RF signal using the RF transmission/reception module and may transmit the amplified RF signal through an antenna.

In operation 510, the electronic device 100 may detect whether overshoot occurs in the PMIC 115. For example, when the voltage supplied to the RF transmission/reception module exceeds a threshold value, an OVP circuit of the RF transmission/reception module may transmit an overvoltage generation signal to an RF integrated circuit through a MIPI bus line, the RF integrated circuit may transmit the overvoltage generation signal to a communication processor, and the communication processor may detect the occurrence of the overshoot by receiving the overvoltage generation signal.

When the occurrence of the overshoot is detected, in operation 515, the electronic device 100 may reduce an operation time of a boost circuit of a voltage converter. For example, the communication processor may reduce the operation time of the boost circuit by reducing the time when the second switch Q2 and the third switch Q3 of the voltage converter 300 of FIG. 3 are turned on, by controlling the PMIC 115.

The electronic device 100 may reduce an amount of current flowing through an output inductor (e.g., the second inductor L2 of FIG. 3) of a buck circuit by reducing the operation time of the boost circuit. As the amount of current flowing through the output inductor (e.g., the second inductor L2 of FIG. 3) of the buck circuit is reduced, the maximum voltage value of the overshoot occurring in the PMIC 115 may be reduced. Damage to an amplification circuit due to overvoltage may be reduced as the maximum voltage value of the overshoot is reduced.

In operation 520, the electronic device 100 may determine whether the occurrence of overshoot of output voltage of the PMIC 115 is detected while transmitting an RF signal for a set time.

In an embodiment, when the occurrence of the overshoot is detected for the set time, in operation 515 again, the electronic device 100 may further reduce the operation time of the boost circuit of the voltage converter. In an embodiment, the electronic device 100 may maintain the operation time of the boost circuit of the voltage converter when the occurrence of the overshoot is detected for the set time.

When the occurrence of the overshoot is not detected for the set time, in operation 525, the electronic device 100 may restore the operation time of the boost circuit to an initial value. For example, the electronic device 100 may restore the operation time of the boost circuit to an operation time before the operation time is reduced.

According to an example method of controlling the voltage according to an embodiment, when the overshoot of the output voltage of the PMIC 115 occurs, the occurrence frequency of the overshoot may be reduced by reducing the operation time of the boost circuit to prevent and/or reduce the overshoot from continuously occurring, and damage caused by overvoltage of the amplification circuit may be reduced.

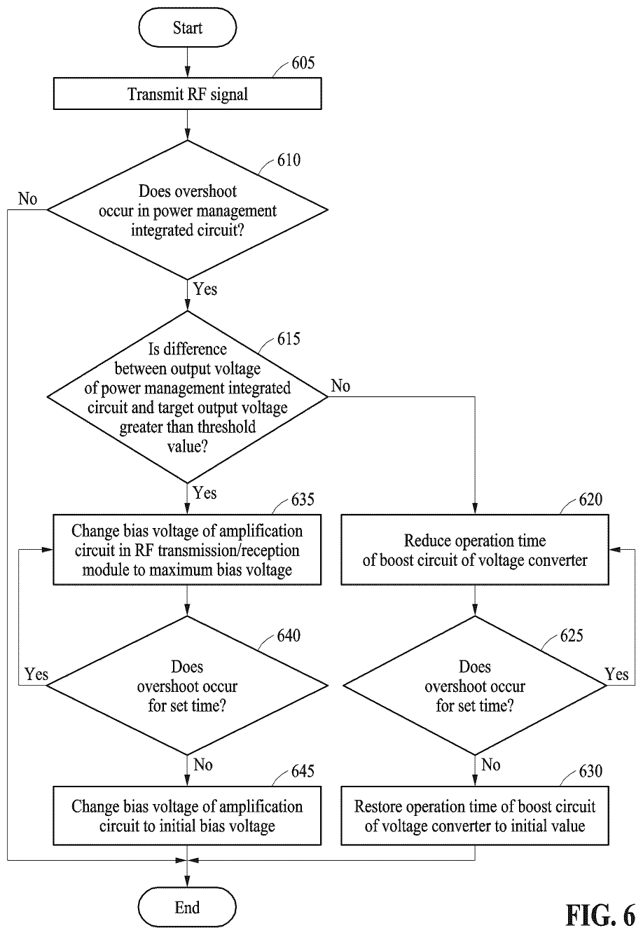

Hereinafter, a method of controlling voltage supplied to an RF transmission/reception module according to an embodiment is described in greater detail with reference to FIG. 6.

FIG. 6 is a flowchart illustrating an example method of controlling voltage supplied to an RF transmission/reception module, according to various embodiments. In operation 605, the electronic device 100 according to an embodiment may transmit an RF signal through an antenna. The electronic device 100 may amplify the RF signal using the RF transmission/reception module and may transmit the amplified RF signal through the antenna.

In operation 610, the electronic device 100 may detect whether overshoot occurs in the PMIC 115. For example, when the voltage supplied to the RF transmission/reception module exceeds a threshold value, an OVP circuit of the RF transmission/reception module may transmit an overvoltage generation signal to an RF integrated circuit through a MIPI bus line, the RF integrated circuit may transmit the overvoltage generation signal to a communication processor, and the communication processor may detect the occurrence of the overshoot by receiving the overvoltage generation signal.

In operation 615, it may be determined whether a difference value between output voltage of the PMIC 115 and target output voltage is greater than a set value in response to the detection of the occurrence of the overshoot. The difference value being greater than the set value may indicate that the output voltage of the PMIC 115 is relatively low and the target output voltage is relatively high, currently (for example, a case in which the output voltage of the PMIC 115 needs to be step up from the lowest output voltage to the maximum output voltage).

The PMIC 115 may maintain the low output voltage when an amplification circuit does not require a lot of power, such as when an amplification circuit, which is a load, is turned off. When the high output voltage of the PMIC 115 is not required, the communication processor may control the PMIC 115 in a pulse-frequency modulation (PFM) method rather than a pulse-width modulation (PWM) method to reduce power consumption. When the PMIC 115 is controlled in the PFM method, current flowing through an inductor (e.g., the first inductor L1 and the second inductor L2 of FIG. 3) of a voltage converter may not be controlled in real time. When the PMIC 115 is controlled in the PFM method, the target output voltage of the PMIC 115 may increase rapidly, so the voltage converter may not be controlled in real time, thereby increasing the probability that overshoot of the output voltage of the PMIC 115 occurs.

When the difference value between the output voltage of the PMIC 115 and the target output voltage is greater than the set value, in operation 635, the electronic device 100 according to an embodiment may increase bias current of the amplification circuit. For example, the electronic device 100 may change the bias current of the amplification circuit to the maximum bias current.

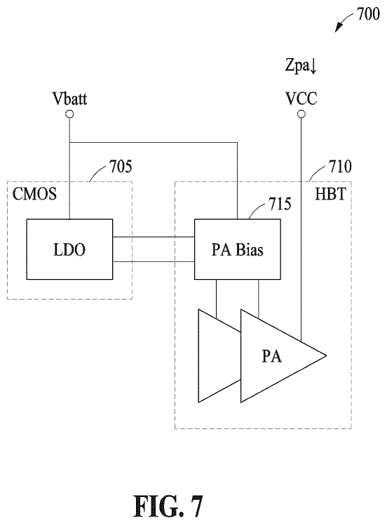

FIG. 7 is a block diagram illustrating an example circuit 700 included in an RF transmission/reception module (e.g., the first RF transmission/reception module 120 and the second RF transmission/reception module 130 of FIG. 1) and configured to control the bias of an amplification circuit according to various embodiments. In an embodiment, the RF transmission/reception module may include a complementary metal-oxide-semiconductor (CMOS) low drop-out voltage (LDO) regulator 705 and a heterojunction bipolar transistor (HBT) amplification circuit 710. A communication processor (e.g., the communication processor 105 of FIG. 1) may increase bias current of the HBT amplification circuit 710 by controlling the CMOS LDO regulator 705. When the bias current increases, the characteristics of the HBT amplification circuit 710 may change (for example, impedance Zpa of the HBT amplification circuit 710 decreases) through a bias circuit 715 included in the HBT amplification circuit 710, and power consumption of the HBT amplification circuit 710 may increase. However, the circuit included in the RF transmission/reception module of FIG. 7 is only an example, and the RF transmission/reception module may include various circuits to control the bias of the amplification circuit.

When the bias current of the amplification circuit increases, voltage required by the amplification circuit, which is a load of the PMIC 115, may increase, and the communication processor may be induced to control the PMIC 115 in the PWM method. By controlling the PMIC 115 in the PWM method, the communication processor may control current flowing through an inductor (e.g., the first inductor L1 and the second inductor L2 of FIG. 3) in a voltage converter of the PMIC 115 in real time and may reduce the maximum voltage value of overshoot.

Referring back to FIG. 6, in operation 640, the electronic device 100 may determine whether the overshoot of the output voltage of the PMIC 115 is detected while transmitting the RF signal for a set time.

In an embodiment, when the occurrence of the overshoot is detected for the set time, the electronic device 100 may further increase the bias current of the amplification circuit in operation 635 again. In an embodiment, when the occurrence of the overshoot is detected for the set time, the electronic device 100 may maintain the bias current of the amplification circuit at the maximum bias current.

When the occurrence of the overshoot is not detected for the set time, in operation 645, the electronic device 100 may change the bias current of the amplification circuit to initial bias current. In an embodiment, the initial bias current may be bias current determined based on transmission power of the RF signal. For example, the initial bias current may be determined based on a table representing a relationship between the transmission power of the RF signal and the bias current of the amplification circuit.

When the difference value between the output voltage and the target output voltage is determined to be less than the set value in operation 615, in operation 620, the electronic device 100 may reduce an operation time of a boost circuit of the voltage converter. For example, the electronic device 100 may reduce the operation time of the boost circuit by reducing the time when the second switch Q2 and the third switch Q3 of the voltage converter 300 of FIG. 3 are turned on.

The electronic device 100 may reduce an amount of current flowing through an output inductor (e.g., the second inductor L2 of FIG. 3) of a buck circuit by reducing the operation time of the boost circuit. As the amount of current flowing through the output inductor (e.g., the second inductor L2 of FIG. 3) of the buck circuit is reduced, the maximum voltage value of the overshoot occurring in the PMIC 115 may be reduced. Damage to the amplification circuit caused by overvoltage may be reduced by reducing the maximum voltage value of the overshoot.

In operation 625, the electronic device 100 may determine whether the occurrence of the overshoot of the output voltage of the PMIC 115 is detected while transmitting the RF signal for the set time.

In an embodiment, when the occurrence of the overshoot is detected for the set time, the electronic device 100 may further reduce the operation time of the boost circuit of the voltage converter in operation 620 again. In an embodiment, the electronic device 100 may maintain the operation time of the boost circuit of the voltage converter when the occurrence of the overshoot is detected for the set time.

When the occurrence of the overshoot is not detected for the set time, in operation 630, the electronic device 100 may restore the operation time of the boost circuit to an initial value. For example, the electronic device 100 may restore the operation time of the boost circuit to an operation time before the operation time is reduced.

According to the method of controlling the voltage according to an embodiment, when the overshoot of the output voltage of the PMIC 115 occurs, the occurrence frequency of the overshoot may be reduced by reducing the operation time of the boost circuit to prevent and/or reduce the overshoot from continuously occurring, and damage caused by overvoltage of the amplification circuit may be reduced.

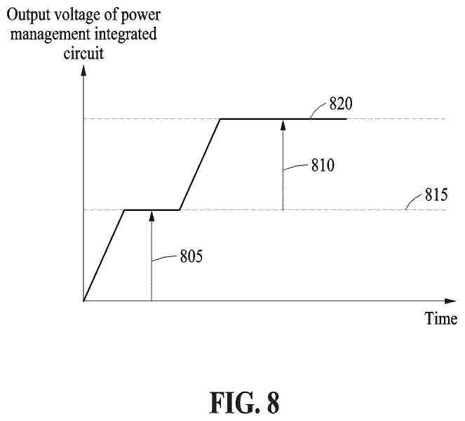

Hereinafter, a method of reducing overshoot of output voltage of a PMIC in an electronic device that does not include an OVP circuit is described in greater detail with reference to FIG. 8.

FIG. 8 is a graph illustrating output voltage of a PMIC controlled by an electronic device, according to various embodiments.

In the embodiment of FIG. 8, the electronic device 100 may not include an OVP circuit (e.g., the first OVP circuit 125 and the second OVP circuit 135 of FIG. 1). When the OVP circuit is not included, a communication processor may not detect whether overvoltage is supplied to an amplification circuit. When it is necessary to rapidly increase output power of the PMIC 115, the electronic device 100 may reduce overshoot of the output voltage of the PMIC 115 without detecting whether overvoltage is supplied to the amplification circuit, by dividing the output power of the PMIC 115 in two stages and increasing the output power.

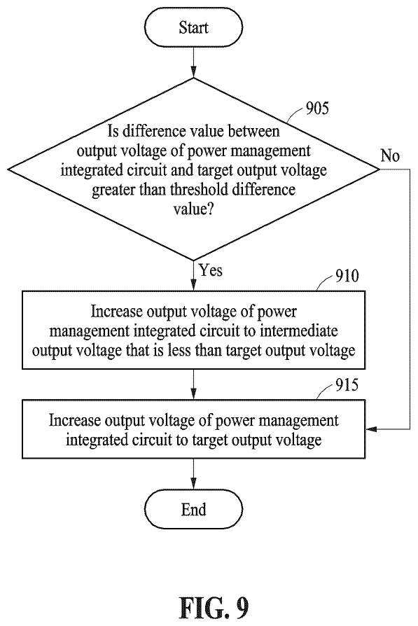

For example, the electronic device 100 may not immediately increase the output voltage of the PMIC 115 to target output voltage 820 but may primarily increase 805 the output voltage to intermediate output voltage 815 that is less than the target output voltage 820 and may secondarily increase 810 the output voltage to the target output voltage 820 after the output voltage of the PMIC 115 reaches the intermediate output voltage 815. FIG. 9 is a flowchart illustrating an example method of controlling voltage supplied to an RF transmission/reception module, according to various embodiments.

In operation 905, the electronic device 100 may determine whether a difference value between output voltage of the PMIC 115 and target output voltage is greater than a threshold difference value.

When the difference value is greater than the threshold difference value in operation 905, in operation 910, the electronic device 100 may primarily increase the output voltage of the PMIC 115 to intermediate output voltage that is less than the target output voltage. For example, a communication processor may primarily increase the output voltage of the PMIC 115 to the intermediate output voltage that is less than the target output voltage by controlling the PMIC 115.

Based on the output voltage of the PMIC 115 reaching the intermediate output voltage, in operation 915, the electronic device 100 may secondarily increase the output voltage of the PMIC 115 to the target output voltage. For example, the communication processor may increase the output voltage of the PMIC 115 to the target output voltage after the output voltage of the PMIC 115 reaches the intermediate output voltage in a steady state. For example, the communication processor may increase the output voltage of the PMIC 115 to the target output voltage after the output voltage of the PMIC 115 reaches the intermediate output voltage and a set time elapses.

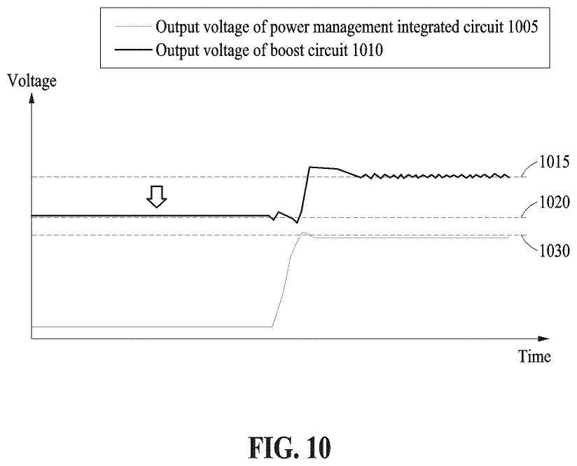

In an embodiment, when the difference value is greater than the threshold difference value in operation 905, the electronic device 100 may further reduce output voltage 1010 of a boost circuit to reduce overshoot of output voltage 1005 of the PMIC 115. For example, referring to FIG. 10, the electronic device 100 may reduce the output voltage 1010 of the boost circuit to voltage 1020 that is less than initial voltage 1015 before increasing the output voltage 1005 of the PMIC 115. For example, the initial voltage 1015 may be 6.8 volts (V), and the voltage 1020 that is less than the initial voltage 1015 may be 5.5V. However, this is only an example, and the initial voltage 1015 and the voltage 1020 that is less than the initial voltage 1015 may have various values. By lowering the output voltage 1010 of the boost circuit before the electronic device 100 steps up the output voltage 1005 of the PMIC 115, the maximum voltage value of the overshoot of the output voltage 1005 of the PMIC 115 may be lowered.

In an embodiment, when the difference value is not greater than the threshold difference value in operation 905, in operation 915, the electronic device 100 may increase the output voltage of the PMIC 115 to the target output voltage.

When the output voltage of the PMIC reaches target output voltage 1030, the electronic device may increase the output voltage of the boost circuit back to the initial voltage 1015.

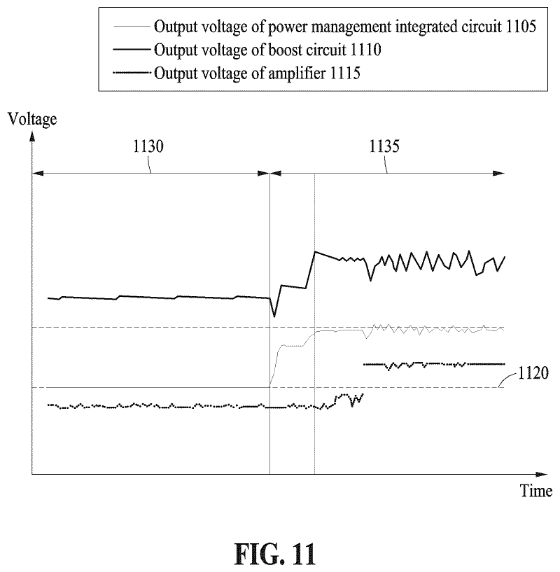

FIG. 11 is a graph illustrating output voltage of a PMIC in a standby mode, according to various embodiments.

In an embodiment, the electronic device 100 may perform wireless communication using frequency division duplexing (FDD). The electronic device 100 may perform a discontinuous transmission (DTX) operation to reduce power consumption while transmitting an RF signal through FDD. For example, the electronic device 100, which does not transmit or receive data to or from a base station for a certain period of time, may perform the DTX operation for low power consumption according to a DTX period allocated under the control by the base station.

When the electronic device 100 performs the DTX operation, the PMIC 115 may operate in a standby mode. For example, the PMIC 115 may operate in at least one of an active mode that supplies power to an RF transmission/reception module (e.g., the first transmission/reception module 120 and the second transmission/reception module 130) when transmitting an RF signal, a standby mode that temporarily stops power supply for power reduction when performing the DTX operation, and a sleep mode that stops power supply when not transmitting an RF signal.

FIG. 11 illustrates, when the electronic device 100 performs the DTX operation, output voltage 1110 of a boost circuit, output voltage 1105 of the PMIC 115, and output voltage 1115 of an amplifier in the RF transmission/reception module (e.g., the first RF transmission/reception module 120 and the second RF transmission/reception module 130). For example, the PMIC 115 may operate in the standby mode in a first time section 1130 and in the active mode in a second time section 1135.

In the standby mode, the PMIC 115 according to an embodiment may supply pre-charging voltage 1120 of a set voltage value rather than 0V (e.g., a certain voltage value that is greater than 0 such as 3V) to the RF transmission/reception module (e.g., the first RF transmission/reception module 120 and the second RF transmission/reception module 130). In the standby mode, the PMIC 115 may reduce the degree of occurrence of overshoot caused by a sudden increase in the output voltage of the PMIC 115, by supplying the pre-charging voltage 1120.

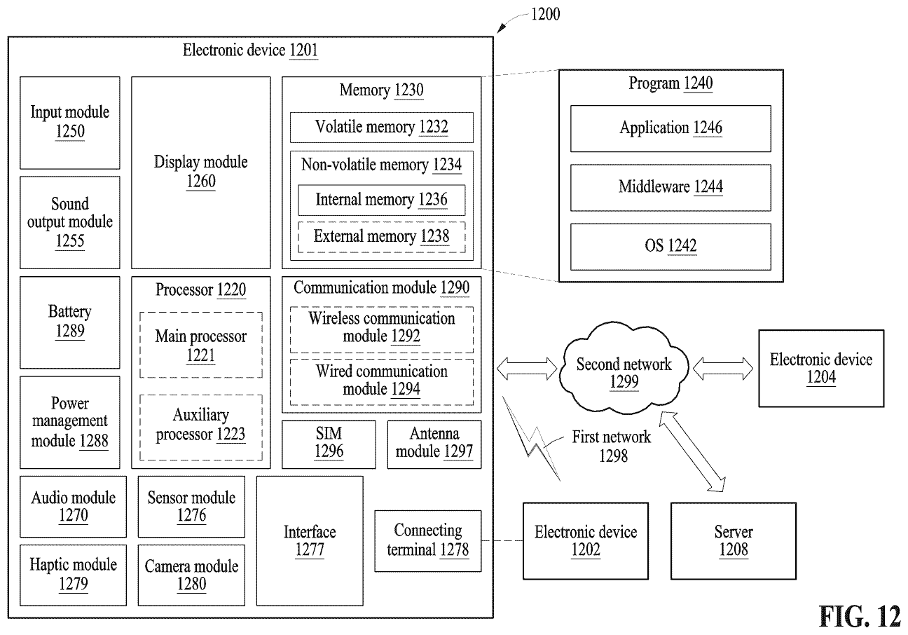

FIG. 12 is a block diagram illustrating an example electronic device 1201 (e.g., the electronic device 100) according to various embodiments. Referring to FIG. 12, the electronic device 1201 in a network environment 1200 may communicate with an electronic device 1202 via a first network 1298 (e.g., a short-range wireless communication network), or communicate with at least one of an electronic device 1204 and a server 1208 via a second network 1299 (e.g., a long-range wireless communication network). According to an embodiment, the electronic device 1201 may communicate with the electronic device 1204 via the server 1208. According to an embodiment, the electronic device 1201 may include a processor 1220, a memory 1230, an input module 1250, a sound output module 1255, a display module 1260, an audio module 1270, and a sensor module 1276, an interface 1277, a connecting terminal 1278, a haptic module 1279, a camera module 1280, a power management module 1288, a battery 1289, a communication module 1290, a subscriber identification module (SIM) 1296, or an antenna module 1297. In various embodiments, at least one of the components (e.g., the connecting terminal 1278) may be omitted from the electronic device 1201, or one or more other components may be added to the electronic device 1201. In various embodiments, some of the components (e.g., the sensor module 1276, the camera module 1280, or the antenna module 1297) may be integrated as a single component (e.g., the display module 1260).

The processor 1220 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 1220 may execute, for example, software (e.g., a program 1240) to control at least one other component (e.g., a hardware or software component) of the electronic device 1201 connected to the processor 1220 and may perform various data processing or computations. According to an embodiment, as at least a part of data processing or computations, the processor 1220 may store a command or data received from another component (e.g., the sensor module 1276 or the communication module 1290) in a volatile memory 1232, process the command or the data stored in the volatile memory 1232, and store resulting data in a non-volatile memory 1234. According to an embodiment, the processor 1220 may include a main processor 1221 (e.g., a central processing unit (CPU) or an application processor (AP)), or an auxiliary processor 1223 (e.g., a graphics processing unit (GPU), a neural processing unit (NPU), an image signal processor (ISP), a sensor hub processor, or a communication processor (CP)) that is operable independently from or in conjunction with the main processor 1221. For example, when the electronic device 1201 includes the main processor 1221 and the auxiliary processor 1223, the auxiliary processor 1223 may be adapted to consume less power than the main processor 1221 or to be specific to a specified function. The auxiliary processor 1223 may be implemented separately from the main processor 1221 or as a part of the main processor 1221.

The auxiliary processor 1223 may control at least some of functions or states related to at least one (e.g., the display module 1260, the sensor module 1276, or the communication module 1290) of the components of the electronic device 1201, instead of the main processor 1221 while the main processor 1221 is in an inactive (e.g., sleep) state or along with the main processor 1221 while the main processor 1221 is an active state (e.g., executing an application). According to an embodiment, the auxiliary processor 1223 (e.g., an ISP or a CP) may be implemented as a portion of another component (e.g., the camera module 1280 or the communication module 1290) that is functionally related to the auxiliary processor 1223. According to an embodiment, the auxiliary processor 1223 (e.g., an NPU) may include a hardware structure specifically for artificial intelligence model processing. An artificial intelligence model may be generated by machine learning. The machine learning may be performed by, for example, the electronic device 1201, in which artificial intelligence is performed, or performed via a separate server (e.g., the server 1208). Learning algorithms may include, but are not limited to, for example, supervised learning, unsupervised learning, semi-supervised learning, or reinforcement learning. The artificial intelligence (AI) model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), and a bidirectional recurrent deep neural network (BRDNN), a deep Q-network, or a combination of two or more thereof, but is not limited thereto. The AI model may additionally or alternatively include a software structure other than the hardware structure.

The memory 1230 may store various pieces of data used by at least one component (e.g., the processor 1220 or the sensor module 1276) of the electronic device 1201. The various pieces of data may include, for example, software (e.g., the program 1240) and input data or output data for a command related thereto. The memory 1230 may include the volatile memory 1232 or the non-volatile memory 1234.

The program 1240 may be stored as software in the memory 1230 and may include, for example, an operating system (OS) 1242, middleware 1244, or an application 1246.

The input module 1250 may receive, from outside (e.g., a user) the electronic device 1201, a command or data to be used by another component (e.g., the processor 1220) of the electronic device 1201. The input module 1250 may include, for example, a microphone, a mouse, a keyboard, a key (e.g., a button), or a digital pen (e.g., a stylus pen).

The sound output module 1255 may output a sound signal to the outside of the electronic device 1201. The sound output module 1255 may include, for example, a speaker or a receiver. The speaker may be used for general purposes, such as playing multimedia or playing a recording. The receiver may be used to receive an incoming call. According to an embodiment, the receiver may be implemented separately from the speaker or as a part of the speaker.

The display module 1260 may visually provide information to the outside (e.g., a user) of the electronic device 1201. The display module 1260 may include, for example, a control circuit for controlling a display, a hologram device, or a projector and control circuitry to control its corresponding one of the display, the hologram device, and the projector. According to an embodiment, the display module 1260 may include a touch sensor adapted to detect a touch, or a pressure sensor adapted to measure the intensity of force of the touch.

The audio module 1270 may convert sound into an electric signal or vice versa. According to an embodiment, the audio module 1270 may obtain the sound via the input module 1250 or output the sound via the sound output module 1255 or an external electronic device (e.g., the electronic device 1202, such as a speaker or headphones) directly or wirelessly connected to the electronic device 1201.

The sensor module 1276 may detect an operational state (e.g., power or temperature) of the electronic device 1201 or an environmental state (e.g., a state of a user) external to the electronic device 1201 and generate an electric signal or data value corresponding to the detected state. According to an embodiment, the sensor module 1276 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1277 may support one or more specified protocols to be used by the electronic device 1201 to couple with the external electronic device (e.g., the electronic device 1202) directly (e.g., by wire) or wirelessly. According to an embodiment, the interface 1277 may include, for example, a high-definition multimedia interface (HDMI), a universal serial bus (USB) interface, a secure digital (SD) card interface, or an audio interface.

The connecting terminal 1278 may include a connector via which the electronic device 1201 may physically connect to an external electronic device (e.g., the electronic device 1202). According to an embodiment, the connecting terminal 1278 may include, for example, an HDMI connector, a USB connector, an SD card connector, or an audio connector (e.g., a headphones connector).

The haptic module 1279 may convert an electric signal into a mechanical stimulus (e.g., a vibration or a movement) or an electrical stimulus, which may be recognized by a user via their tactile sensation or kinesthetic sensation. According to an embodiment, the haptic module 1279 may include, for example, a motor, a piezoelectric element, or an electric stimulator.

The camera module 1280 may capture a still image and moving images. According to an embodiment, the camera module 1280 may include one or more lenses, image sensors, ISPs, and flashes.

The power management module 1288 may manage power supplied to the electronic device 1201. According to an embodiment, the power management module 1288 may be implemented as, for example, at least a part of a power management integrated circuit (PMIC).

The battery 1289 may supply power to at least one component of the electronic device 1201. According to an embodiment, the battery 1289 may include, for example, a primary cell, which is not rechargeable, a secondary cell, which is rechargeable, or a fuel cell.

The communication module 1290 may support establishing a direct (e.g., wired) communication channel or a wireless communication channel between the electronic device 1201 and the external electronic device (e.g., the electronic device 1202, the electronic device 1204, or the server 1208) and performing communication via the established communication channel. The communication module 1290 may include one or more CPs that are operable independently from the processor 1220 (e.g., an AP) and that support direct (e.g., wired) communication or wireless communication. According to an embodiment, the communication module 1290 may include a wireless communication module 1292 (e.g., a cellular communication module, a short-range wireless communication module, or a global navigation satellite system (GNSS) communication module) or a wired communication module 1294 (e.g., a local area network (LAN) communication module, or a power line communication (PLC) module). A corresponding one of these communication modules may communicate with the external electronic device, for example, the electronic device 1204, via the first network 1298 (e.g., a short-range communication network, such as Bluetooth™, wireless-fidelity (Wi-Fi) direct, or infrared data association (IrDA)) or the second network 1299 (e.g., a long-range communication network, such as a legacy cellular network, a 5G network, a next-generation communication network, the Internet, or a computer network (e.g., a LAN or a wide area network (WAN)). These various types of communication modules may be implemented as a single component (e.g., a single chip), or may be implemented as multiple components (e.g., multiple chips) separate from each other. The wireless communication module 1292 may identify and authenticate the electronic device 1201 in a communication network, such as the first network 1298 or the second network 1299, using subscriber information (e.g., international mobile subscriber identity (IMSI)) stored in the SIM 1296.

The wireless communication module 1292 may support a 5G network after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 1292 may support a high-frequency band (e.g., a mmWave band) to achieve, e.g., a high data transmission rate. The wireless communication module 1292 may support various technologies for securing performance on a high-frequency band, such as, e.g., beamforming, massive multiple-input and multiple-output (MIMO), full dimensional MIMO (FD-MIMO), an array antenna, analog beam-forming, or a large scale antenna. The wireless communication module 1292 may support various requirements specified in the electronic device 1201, an external electronic device (e.g., the electronic device 1204), or a network system (e.g., the second network 1299). According to an embodiment, the wireless communication module 1292 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 1297 may transmit or receive a signal or power to or from the outside (e.g., the external electronic device) of the electronic device 1201. According to an embodiment, the antenna module 1297 may include an antenna including a radiating element including a conductive material or a conductive pattern formed in or on a substrate (e.g., a printed circuit board (PCB)). According to an embodiment, the antenna module 1297 may include a plurality of antennas (e.g., an antenna array). In such a case, at least one antenna appropriate for a communication scheme used in a communication network, such as the first network 1298 or the second network 1299, may be selected by, for example, the communication module 1290 from the plurality of antennas. The signal or power may be transmitted or received between the communication module 1290 and the external electronic device via the at least one selected antenna. According to an embodiment, another component (e.g., a radio frequency integrated circuit (RFIC)) other than the radiating element may be additionally formed as a part of the antenna module 1297.

According to various embodiments, the antenna module 1297 may form a mmWave antenna module. According to an embodiment, the mm Wave antenna module may include a PCB, an RFIC on a first surface (e.g., the bottom surface) of the PCB, or adjacent to the first surface of the PCB and capable of supporting a designated high-frequency band (e.g., a mm Wave band), and a plurality of antennas (e.g., array antennas) disposed on a second surface (e.g., the top or a side surface) of the PCB, or adjacent to the second surface of the PCB and capable of transmitting or receiving signals of the designated high-frequency band.

At least some of the above-described components may be coupled mutually and exchange signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1201 and the external electronic device (e.g., the electronic device 1204) via the server 1208 coupled with the second network 1299. Each of the external electronic devices (e.g., the electronic device 1202 or 1204) may be a device of the same type as or a different type from the electronic device 1201. According to an embodiment, all or some of operations to be executed by the electronic device 1201 may be executed by one or more external electronic devices (e.g., the electronic devices 1202 and 1204 and the server 1208). For example, if the electronic device 1201 needs to perform a function or a service automatically, or in response to a request from a user or another device, the electronic device 1201, instead of, or in addition to, executing the function or the service, may request the one or more external electronic devices to perform at least part of the function or service. The one or more external electronic devices receiving the request may perform the at least part of the function or service, or an additional function or an additional service related to the request and may transfer a result of the performance to the electronic device 1201. The electronic device 1201 may provide the result, with or without further processing the result, as at least part of a response to the request. To that end, cloud computing, distributed computing, mobile edge computing (MEC), or client-server computing technology may be used, for example. The electronic device 1201 may provide ultra low-latency services using, e.g., distributed computing or MEC. In an embodiment, the external electronic device (e.g., the electronic device 1204) may include an Internet-of-things (IoT) device. The server 1208 may be an intelligent server using machine learning and/or a neural network. According to an embodiment, the external electronic device (e.g., the electronic device 1204) or the server 1208 may be included in the second network 1299. The electronic device 1201 may be applied to intelligent services (e.g., a smart home, a smart city, a smart car, or healthcare) based on 5G communication technology or IoT-related technology.

The electronic device according to various embodiments may be one of various types of electronic devices. The electronic device may include, for example, a portable communication device (e.g., a smartphone), a computer device, a portable multimedia device, a portable medical device, a camera, a wearable device, a home appliance device, or the like. According to an embodiment of the disclosure, the electronic device is not limited to those described above.

It should be understood that various embodiments of the present disclosure and the terms used therein are not intended to limit the technological features set forth herein to particular embodiments and include various changes, equivalents, or replacements for a corresponding embodiment. In connection with the description of the drawings, like reference numerals may be used for similar or related components. It is to be understood that a singular form of a noun corresponding to an item may include one or more of the things unless the relevant context clearly indicates otherwise. As used herein, “A or B”, “at least one of A and B”, “at least one of A or B”, “A, B or C”, “at least one of A, B and C”, and “A, B, or C,” each of which may include any one of the items listed together in the corresponding one of the phrases, or all possible combinations thereof. Terms such as “first”, “second”, or “first” or “second” may simply be used to distinguish the component from other components in question, and do not limit the components in other aspects (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., by wire), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 1240) including one or more instructions that are stored in a storage medium (e.g., the internal memory 1236 or the external memory 1238) that is readable by a machine (e.g., the electronic device 1201). For example, a processor (e.g., the processor 1220) of the machine (e.g., the electronic device 1201) may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., a compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as a memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

An electronic device according to an example embodiment may include: a communication processor including at least one processor comprising processing circuitry, an RF integrated circuit configured to generate an RF signal by processing data received from the communication processor and configured to transmit the RF signal to an RF transmission/reception module (e.g., the first RF transmission/reception module 120 or the second RF transmission/reception module 130 of FIG. 1), the RF transmission/reception module (e.g., the first RF transmission/reception module 120 or the second RF transmission/reception module 130 of FIG. 1) including: an amplification circuit configured to amplify the RF signal and an overvoltage protection (OVP) circuit (e.g., the first OVP circuit 125 or the second OVP circuit 135 of FIG. 1) configured to reduce damage to the amplification circuit due to overvoltage, and configured to transmit the amplified RF signal, and a power management integrated circuit (PMIC) configured to manage power supplied to the amplification circuit using a voltage converter including the boost circuit configured to step up voltage input to the boost circuit and a buck circuit configured to step down voltage input to the buck circuit, wherein at least one processor of the communication processor, individually and/or collectively, is configured to: detect the occurrence of overshoot in which voltage supplied to the RF transmission/reception module (e.g., the first RF transmission/reception module 120 or the second RF transmission/reception module 130 of FIG. 1) exceeds a threshold value, using the OVP circuit (e.g., the first OVP circuit 125 or the second OVP circuit 135 of FIG. 1); and reduce an operation time of the boost circuit by controlling the PMIC in response to the detection of the occurrence of the overshoot.

In an example embodiment, least one processor of communication processor, individually and/or collectively, may be configured to: determine whether the occurrence of the overshoot is detected for a set time after the operation time of the boost circuit is reduced, using the OVP circuit (e.g., the first OVP circuit 125 or the second OVP circuit of FIG. 1) and restore the operation time of the boost circuit to an initial value based on the occurrence of the overshoot not being detected for the set time.

In an example embodiment, the buck circuit may be connected to the boost circuit in a cascade structure.

In an example embodiment, at least one processor of the communication processor, individually and/or collectively, may be configured to reduce an amount of current flowing through an output inductor of the buck circuit by reducing the operation time of the boost circuit.

In an example embodiment, the OVP circuit (e.g., the first OVP circuit 125 or the second OVP circuit 135 of FIG. 1) may be configured to: transmit an overvoltage generation signal to the RF integrated circuit through a MIPI bus line based on the voltage supplied to the RF transmission/reception module (e.g., the first RF transmission/reception module 120 or the second RF transmission/reception module 130 of FIG. 1) exceeding the threshold value, in which the RF integrated circuit may transmit the overvoltage generation signal to the communication processor, and in which at least one processor of the communication processor, individually and/or collectively may be configured to detect the occurrence of the overshoot when the overvoltage generation signal is received.

An electronic device according to an example embodiment may include a communication processor including at least one processor, comprising processing circuitry, an RF integrated circuit configured to generate an RF signal by processing data received from the communication processor and configured to transmit the RF signal to an RF transmission/reception module (e.g., the first RF transmission/reception module 120 or the second RF transmission/reception module 130 of FIG. 1), the RF transmission/reception module (e.g., the first RF transmission/reception module 120 or the second RF transmission/reception module 130 of FIG. 1) including: an amplification circuit configured to amplify the RF signal and an overvoltage protection (OVP) circuit (e.g., the first OVP circuit 125 or the second OVP circuit 135 of FIG. 1) configured to reduce damage to the amplification circuit due to overvoltage, and configured to transmit the amplified RF signal, and a power management integrated circuit (PMIC) configured to manage power supplied to the amplification circuit using a voltage converter including a boost circuit configured to step up voltage input to the boost circuit and a buck circuit configured to step down voltage input to the buck circuit, wherein at least one processor of the communication processor, individually and/or collectively, may be configured to: detect occurrence of overshoot in which voltage supplied to the RF transmission/reception module (e.g., the first RF transmission/reception module 120 or the second RF transmission/reception module 130 of FIG. 1) exceeds a threshold value, using the OVP circuit (e.g., the first OVP circuit 125 or the second OVP circuit 135 of FIG. 1), determine whether a difference value between output voltage of the PMIC and target output voltage is greater than a set value in response to the detection of the occurrence of the overshoot, and change bias current of the amplification circuit to maximum bias current based on the difference value being greater than the set value.

In an example embodiment, at least one processor of the communication processor, individually and/or collectively, may be configured to: reduce an operation time of the boost circuit by controlling the PMIC based on the difference value being less than the set value.

In an example embodiment, at least one processor, individually and/or collectively, of the communication processor, may be configured to: determine whether the occurrence of the overshoot is detected for a set time based on the bias current being changed to the maximum bias current, using the OVP circuit (e.g., the first using the OVP circuit 125 or the second using the OVP circuit 135 of FIG. 1) and change the bias current to initial bias current based on the occurrence of the overshoot not being detected for the set time.

In an example embodiment, the PMIC may be controlled by at least one processor, of the communication processor, individually and/or collectively, in a PFM method based on the amplification circuit being in an off state and controlled by at least one processor of the communication processor, individually and/or collectively, in a PWM method based on the bias current being changed to the maximum bias current.

In an example embodiment, the OVP circuit (e.g., the first OVP circuit 125 or the second OVP circuit 135 of FIG. 1) may be configured to transmit an overvoltage generation signal to the RF integrated circuit through a MIPI bus line based on the voltage supplied to the RF transmission/reception module (e.g., the first RF transmission/reception module 120 or the second RF transmission/reception module 130 of FIG. 1) exceeding the threshold value, in which the RF integrated circuit may transmit the overvoltage generation signal to the communication processor, and in which at least one processor of the communication processor, may be configured to detect the occurrence of the overshoot based on the overvoltage generation signal being received.

An electronic device according to an example embodiment may include: a communication processor including at least one processor comprising processing circuitry, an RF integrated circuit configured to generate an RF signal by processing data received from the communication processor and configured to transmit the RF signal to an RF transmission/reception module (e.g., the first RF transmission/reception module 120 or the second RF transmission/reception module 130 of FIG. 1), the RF transmission/reception module (e.g., the first RF transmission/reception module or the second RF transmission/reception module of FIG. 1) including: an amplification circuit configured to amplify the RF signal and configured to transmit the amplified RF signal, and a power management integrated circuit (PMIC) configured to manage power supplied to the amplification circuit using a voltage converter including a boost circuit configured to step up voltage input to the boost circuit and a buck circuit configured to step down voltage input to the buck circuit, in which at least one processor of the communication processor, individually and/or collectively, may be configured to: determine whether a difference value between output voltage of the PMIC and target output voltage is greater than a threshold difference value, increase the output voltage of the PMIC to an intermediate output voltage less than the target output voltage by controlling the PMIC based on the difference value being greater than the threshold difference value, and increase the output voltage of the PMIC to the target output voltage based on the output voltage of the PMIC reaching the intermediate output voltage.

In an example embodiment, at least one processor of the communication processor, individually and/or collectively, may be configured to increase the output voltage of the PMIC to the target output voltage based on the output voltage of the PMIC reaching the intermediate output voltage in a steady state.

In an example embodiment, at least one processor of the communication processor, individually and/or collectively, may be configured to increase the output voltage of the PMIC to the target output voltage based on the output voltage of the PMIC reaching the intermediate output voltage and a set time elapsing.

In an example embodiment, the buck circuit may be connected to the boost circuit in a cascade structure.

In an example embodiment, at least one processor of the communication processor, individually and/or collectively, may be configured to: reduce output voltage of the boost circuit based on the difference value being greater than the threshold difference value, and based on the output voltage of the PMIC reaching the target output voltage, increase the output voltage of the boost circuit to output voltage of the boost circuit before the output voltage is reduced.

According to an example embodiment, a method of controlling voltage supplied to an RF transmission/reception module (e.g., the first RF transmission/reception module 120 or the second RF transmission/reception module 130 of FIG. 1) configured to transmit and receive an RF signal to and from the electronic device may include: detecting occurrence of overshoot in which the voltage supplied to the RF transmission/reception module (e.g., the first RF transmission/reception module 120 or the second RF transmission/reception module 130 of FIG. 1) exceeds a threshold value, using an overvoltage protection (OVP) circuit (e.g., the first OVP circuit 125 or the second OVP circuit 135 of FIG. 1) configured to reduce an amplification circuit, included in the RF transmission/reception module (e.g., the first RF transmission/reception module 120 or the second RF transmission/reception module 130 of FIG. 1) and to amplify an RF signal to be transmitted, from being damaged due to overvoltage, and using a voltage converter including a boost circuit and a buck circuit in response to the detection of the occurrence of the overshoot, reducing an operation time of the boost circuit by controlling a power management integrated circuit (PMIC) configured to supply power to the RF transmission/reception module (e.g., the first RF transmission/reception module 120 or the second RF transmission/reception module 130 of FIG. 1).

In an example embodiment, method may further include determining whether the occurrence of the overshoot is detected for a set time based on the operation time of the boost circuit being reduced, using the OVP circuit (e.g., the first OVP circuit 125 or the second OVP circuit 135 of FIG. 1) and restoring the operation time of the boost circuit to an initial value based on the occurrence of the overshoot not being detected for the set time.

In an example embodiment, the voltage converter may include a voltage converter in which a buck converter is connected to the boost circuit in a cascade structure. In an example embodiment, the detecting of the occurrence of the overshoot may include: transmitting an overvoltage generation signal of the OVP circuit (e.g., the first OVP circuit 125 or the second OVP circuit 135 of FIG. 1) to the RF integrated circuit configured to generate an RF signal to be transmitted, through a MIPI bus line based on the voltage supplied to the RF transmission/reception module (e.g., the first transmission/reception module 120 or the second transmission/reception module 130 of FIG. 1) exceeding the threshold value, transmitting the overvoltage generation signal from the RF integrated circuit to the communication processor of the electronic device, and detecting the occurrence of the overshoot by the communication processor that receives the overvoltage generation signal.

According to the method of controlling the voltage supplied to the RF transmission/reception module and the electronic device for performing the same according to various embodiments of the present disclosure, it may be possible to reduce damage to the amplification circuit due to the overshoot in which the voltage supplied to the amplification circuit exceeds the target voltage by controlling the output voltage of the PMIC.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. An electronic device comprising:
a communication processor including at least one processor comprising processing circuitry;
a radio frequency (RF) integrated circuit configured to generate an RF signal by processing data received from the communication processor and configured to transmit the RF signal to an RF transmission/reception module;
the RF transmission/reception module comprising: an amplification circuit configured to amplify the RF signal and an overvoltage protection (OVP) circuit configured to reduce damage to the amplification circuit due to overvoltage, and configured to transmit the amplified RF signal; and
a power management integrated circuit (PMIC) configured to manage power supplied to the amplification circuit using a voltage converter comprising a boost circuit configured to step up voltage input to the boost circuit and a buck circuit configured to step down voltage input to the buck circuit,
wherein at least one processor of the communication processor, individually and/or collectively, is configured to:
detect occurrence of overshoot in which voltage supplied to the RF transmission/reception module exceeds a threshold value, using the OVP circuit; and
reduce an operation time of the boost circuit by controlling the PMIC in response to the detection of the occurrence of the overshoot.

2. The electronic device of claim 1, wherein at least one processor of the communication processor, individually and/or collectively, is configured to:
determine whether the occurrence of the overshoot is detected for a set time based on the operation time of the boost circuit being reduced, using the OVP circuit; and
restore the operation time of the boost circuit to an initial value based on the occurrence of the overshoot not being detected for the set time.

3. The electronic device of claim 1, wherein the buck circuit is connected to the boost circuit in a cascade structure.

4. The electronic device of claim 3, wherein at least one processor of the communication processor, individually and/or collectively, is configured to reduce an amount of current flowing through an output inductor of the buck circuit by reducing the operation time of the boost circuit.

5. The electronic device of claim 1, wherein the OVP circuit is configured to transmit an overvoltage generation signal to the RF integrated circuit through a mobile industry processor interface (MIPI) bus line based on the voltage supplied to the RF transmission/reception module exceeding the threshold value,
wherein the RF integrated circuit is configured to transmit the overvoltage generation signal to the communication processor, and
wherein at least one processor of the communication processor, individually and/or collectively, is configured to detect the occurrence of the overshoot based on the overvoltage generation signal being received.

6. An electronic device comprising:
a communication processor including at least one processor comprising processing circuitry;
a radio frequency (RF) integrated circuit configured to generate an RF signal by processing data received from the communication processor and configured to transmit the RF signal to an RF transmission/reception module;
the RF transmission/reception module comprising an amplification circuit configured to amplify the RF signal and an overvoltage protection (OVP) circuit configured to reduce damage to the amplification circuit due to overvoltage, and configured to transmit the amplified RF signal; and
a power management integrated circuit (PMIC) configured to manage power supplied to the amplification circuit using a voltage converter comprising a boost circuit configured to step up voltage input to the boost circuit and a buck circuit configured to step down voltage input to the buck circuit,
wherein at least one processor of the communication processor, individually and/or collectively, is configured to:
detect occurrence of overshoot in which voltage supplied to the RF transmission/reception module exceeds a threshold value, using the OVP circuit;
determine whether a difference value between output voltage of the PMIC and target output voltage is greater than a set value in response to the detection of the occurrence of the overshoot; and
change bias current of the amplification circuit to maximum bias current based on the difference value being greater than the set value.

7. The electronic device of claim 6, wherein at least one processor of the communication processor, individually and/or collectively, is configured to reduce an operation time of the boost circuit by controlling the PMIC based on the difference value being less than the set value.

8. The electronic device of claim 6, wherein at least one processor of the communication processor, individually and/or collectively, is configured to:
determine whether the occurrence of the overshoot is detected for a set time based on the bias current being changed to the maximum bias current, using the OVP circuit; and
change the bias current to initial bias current based on the occurrence of the overshoot not being detected for the set time.

9. The electronic device of claim 6, wherein the PMIC is configured to be:
controlled by at least one processor of the communication processor in a pulse-frequency modulation (PFM) method based on the amplification circuit being in an off state; and
controlled by at least one processor of the communication processor in a pulse-width modulation (PWM) method based the bias current being changed to the maximum bias current.

10. The electronic device of claim 6, wherein the OVP circuit is configured to transmit an overvoltage generation signal to the RF integrated circuit through a mobile industry processor interface (MIPI) bus line based on the voltage supplied to the RF transmission/reception module exceeding the threshold value,
wherein the RF integrated circuit is configured to transmit the overvoltage generation signal to the communication processor, and
wherein at least one processor of the communication processor, individually and/or collectively, is configured to detect the occurrence of the overshoot based on the overvoltage generation signal being received.

11. An electronic device comprising:
a communication processor including at least one processor comprising processing circuitry;
a radio frequency (RF) integrated circuit configured to generate an RF signal by processing data received from the communication processor and configured to transmit the RF signal to an RF transmission/reception module;
the RF transmission/reception module comprising an amplification circuit configured to amplify the RF signal, and configured to transmit the amplified RF signal; and
a power management integrated circuit (PMIC) configured to manage power supplied to the amplification circuit using a voltage converter comprising a boost circuit configured to step up voltage input to the boost circuit and a buck circuit configured to step down voltage input to the buck circuit,
wherein at least one processor of the communication processor, individually and/or collectively, is configured to:
determine whether a difference value between output voltage of the PMIC and target output voltage is greater than a threshold difference value;
increase the output voltage of the PMIC to intermediate output voltage less than the target output voltage by controlling the PMIC based on the difference value being greater than the threshold difference value; and
increase the output voltage of the PMIC to the target output voltage based on the output voltage of the PMIC reaching the intermediate output voltage.

12. The electronic device of claim 11, wherein at least one processor of the communication processor, individually and/or collectively, is configured to increase the output voltage of the PMIC to the target output voltage based on the output voltage of the PMIC reaching the intermediate output voltage in a steady state.

13. The electronic device of claim 11, wherein at least one processor of the communication processor is configured to increase the output voltage of the PMIC to the target output voltage based on the output voltage of the PMIC reaching the intermediate output voltage and a set time elapsing.

14. The electronic device of claim 11, wherein at least one processor of the communication processor, individually and/or collectively, is configured to:
reduce output voltage of the boost circuit based on the difference value being greater than the threshold difference value; and
based on the output voltage of the PMIC reaching the target output voltage, increase the output voltage of the boost circuit to output voltage of the boost circuit before the output voltage is reduced.

15. A method of controlling voltage supplied to a radio frequency (RF) transmission/reception module configured to transmit and receive an RF signal to and from an electronic device, the method comprising:
detecting occurrence of overshoot in which the voltage supplied to the RF transmission/reception module exceeds a threshold value, using an overvoltage protection (OVP) circuit configured to reduce an amplification circuit, included in the RF transmission/reception module configured to amplify an RF signal to be transmitted, from being damaged due to overvoltage; and
using a voltage converter comprising a boost circuit and a buck circuit, reducing an operation time of the boost circuit by controlling a power management integrated circuit (PMIC) configured to supply power to the RF transmission/reception module in response to the detection of the occurrence of the overshoot.
